(19) United States
(12) Patent Application Publication
(10) Pub. No.: US 2026/0337012 A1
(43) Pub. Date: Oct. 29, 2026

(54) DUAL-AXIS ANGLE FEEDBACK MEMS MICROMIRROR AND MANUFACTURING METHOD THEREOF

(71) Applicants: Anhui China Science MW Electronic Technology Co., Ltd., Bengbu (CN); Shanghai Zike Electronic Technology R&D Co., Ltd., Shanghai (CN)

(72) Inventors: Wei LI, Bengbu (CN); Jing XU, Bengbu (CN); Xiaowei WANG, Bengbu (CN)

(73) Assignees: Anhui China Science MW Electronic Technology Co., Ltd., Bengbu (CN); Shanghai Zike Electronic Technology R&D Co., Ltd., Shanghai (CN)

(21) Appl. No.: 18/995,813

(22) PCT Filed: Nov. 20, 2023
(86) PCT No.: PCT/CN2023/132624

§ 371 Date: Jan. 16, 2025

(30) Foreign Application Priority Data
Oct. 27, 2023 (CN) 202311403175.2

(51) Int. Cl. B81B 7/02; B81B 5/00; B81C 1/00

(52) U.S. Cl. CPC B81B 7/02; B81B 5/00; B81C 1/00198; B81C 1/00523

(57) ABSTRACT

A dual-axis angle feedback MEMS micromirror and a manufacturing method thereof. The MEMS micromirror includes comb structures. Each comb structure includes movable combs, fixed drive combs, and fixed feedback combs. The movable combs and the fixed drive combs form drive comb groups, and the movable combs and the fixed feedback combs form feedback comb groups. Without affecting the performance and volume of the MEMS micromirror, the present invention provides feedback comb groups that are easily compatible and integrable. The number of feedback comb groups is essentially equivalent to that of the drive comb groups, enabling a larger change in the feedback capacitance of the MEMS micromirror. This allows for more precise closed-loop control of the micromirror's rotation angle through variations in feedback capacitance. The MEMS micromirror is compact, highly integrated, fully compatible with manufacturing technologies, cost-effective, and contributes to the further expansion of the application field of MEMS micromirror.

### FIELD OF THE INVENTION

The present invention relates to the technical field of microelectromechanical systems (MEMS), specifically relates to a dual-axis angle feedback MEMS micromirror and a manufacturing method thereof.

### BACKGROUND OF THE INVENTION.

MEMS micromirrors have become increasingly widely used in industrial and consumer fields, such as in lidar, projection displays, and 3D cameras. Under unstable environmental factors such as temperature, humidity, vibration and shock, the scanning accuracy of MEMS micromirrors may be affected and even lead to failure. Therefore, it is crucial to control the deflection angle of the MEMS micromirror through closed-loop feedback and use the circuit system to maintain a certain level of stability in the micromirror's deflection angle.

In the prior art, the deflection angle of MEMS micromirrors is typically monitored using four methods: piezoelectric feedback, capacitive feedback, photoelectric feedback, and piezoresistive feedback. Among them, the comb-based capacitive feedback does not require any additional components or packaging, nor does it need extra fabrication processes, making it easy to integrate. There are generally two types of capacitive feedback methods: one is to use the same group of combs as both the drive combs and the capacitive feedback combs. This method is extremely difficult to process and demodulate drive signals. The other method is to set up independent drive comb groups and capacitive feedback comb groups in the structure of the device. The independent drive comb groups and capacitive feedback comb groups are typically arranged in parallel. This method offers good compatibility and integration, but it typically sacrifices the number of driving combs, thereby reducing the driving force of the MEMS micromirror or potentially affecting its performance. Therefore, it is challenging to set up and integrate the capacitive feedback comb groups and the drive comb groups independently without reducing the driving force of the MEMS micromirror or affecting its structure and performance.

Therefore, it is an urgent issue to achieve a configuration of the drive comb groups and the capacitive feedback comb groups that does not affect the structure and performance of the MEMS micromirror, while also enhancing their compatibility and integration.

### SUMMARY OF THE INVENTION

The present invention provides a dual-axis angle feedback MEMS micromirror and a manufacturing method thereof. The MEMS micromirror includes comb structures. Each of the comb structures includes movable combs, fixed drive combs, and fixed feedback combs, where the movable combs and the fixed drive combs form drive comb groups, and the movable combs and the fixed feedback combs form feedback comb groups. Without affecting the performance and volume of the MEMS micromirror, the present invention provides feedback comb groups that are easily compatible and integrable. The number of feedback comb groups is essentially equivalent to that of the drive comb groups, enabling a larger change in the feedback capacitance of the MEMS micromirror. This allows for more precise closed-loop control of the micromirror's rotation angle through variations in feedback capacitance. Additionally, the MEMS micromirror provided by the present invention is compact, highly integrated, fully compatible with manufacturing technologies, cost-effective, and contributes to the further expansion of the application field of MEMS micromirror.

A dual-axis angle feedback MEMS micromirror includes:

an inner frame; an outer frame, disposed around the inner frame;

a movable reflector, disposed inside the inner frame;

elastic beams, including first elastic beams and second elastic beams, where the first elastic beams are symmetrically disposed on two sides of the movable reflector along a first direction for connecting the inner frame to the movable reflector, and the second elastic beams are symmetrically disposed on two sides of the movable reflector along a second direction perpendicular to the first direction for connecting the inner frame to the outer frame; and

comb structures, disposed between the inner frame and the movable reflector, and between the inner frame and the outer frame, and configured to respectively drive the movable reflector to rotate around the first elastic beams or the second elastic beams.

Each of the comb structures includes movable combs, fixed drive combs and fixed feedback combs. The fixed feedback combs are disposed above the fixed drive combs and in the same plane as the movable combs. The projections of the fixed drive combs and the movable combs are staggered in a horizontal plane. The fixed drive combs of a first subset of the comb structures disposed between the inner frame and the movable reflector are connected to the inner sides of the inner frame. The fixed drive combs of a second subset of the comb structures disposed between the inner frame and the outer frame are connected to the inner sides of the outer frame.

The present invention further provides a manufacturing method of a dual-axis angle feedback MEMS micromirror. The method is used to prepare the above MEMS micromirror, including the following steps:

providing a bonded structure including a substrate, a first device layer, a first insulation layer, a second device layer, and a second insulation layer stacked sequentially, where at least fixed drive combs are formed in the first device layer;

etching the second insulation layer and the second device layer to form movable combs, fixed feedback combs, a movable reflector, first elastic beams, second elastic beams and lower comb electrode lead grooves in the second device layer, where the fixed feedback combs are provided coaxially with the fixed drive combs, and the projections of the fixed drive combs and the movable combs onto a horizontal plane are staggered; and

removing the second insulation layer and the exposed first insulation layer.

A metal reflective layer is formed on the surface of the movable reflector, a movable comb electrode and a fixed feedback comb electrode are formed on the surface of the outer frame in the second device layer, and lower comb electrodes exposed on the surface of the outer frame are formed in the lower comb electrode lead grooves. Different electrodes are isolated from each other.

The dual-axis angle feedback MEMS micromirror and the manufacturing method thereof provided by the present invention at least have the following beneficial effects:

the MEMS micromirror provided by the present invention includes comb structures, and each of the comb structures includes movable combs, fixed drive combs, and fixed feedback combs, where the movable combs and the fixed drive combs form drive comb groups, and the movable combs and the fixed feedback combs form feedback comb groups. Without affecting the performance and volume of the MEMS micromirror, the present invention provides feedback comb groups that are easily compatible and integrable. The number of feedback comb groups is essentially equivalent to that of the drive comb groups, enabling a larger change in the feedback capacitance of the MEMS micromirror. This allows for more precise closed-loop control of the micromirror's rotation angle through variations in feedback capacitance. Additionally, the MEMS micromirror provided by the present invention is compact, highly integrated, fully compatible with manufacturing technologies, cost-effective, and contributes to the further expansion of the application field of MEMS micromirror.

The manufacturing method of the dual-axis angle feedback MEMS micromirror provided by the present invention also has the above beneficial effects.

### BRIEF DESCRIPTION OF DRAWINGS

FIG. 1 shows a top view of a MEMS micromirror according to Embodiment 1 and Embodiment 2.

FIG. 2a shows a top view of a comb structure according to Embodiment 1 and Embodiment 2.

FIG. 2b shows a cross-sectional view of the comb structure in FIG. 2a according to Embodiment 1 and Embodiment 2, with the cutting plane parallel to the Y direction and perpendicular to the X direction.

FIGS. 3a to 3b show cross-sectional views of a MEMS micromirror according to Embodiment 1.

FIGS. 4a to 4b show cross-sectional views of a MEMS micromirror according to Embodiment 2.

FIGS. 5a to 5f show cross-sectional views of a MEMS micromirror prepared in steps S1 to S3 according to Embodiment 3.

FIGS. 6a to 6d show cross-sectional views of a bonded structure in different steps according to Embodiment 4.

### Reference Numerals

10 inner frame
20 outer frame
30 movable reflector
40 comb structure
41 movable comb
42 fixed drive comb
43 fixed feedback comb
51 first elastic beam
52 second elastic beam
53 supplementary elastic beam
61 upper comb electrode 500 base layer
62 lower comb electrode
63 metal reflective layer
100 substrate
101 slot
200 first device layer
300 second device layer
400 insulation layer
401 isolation slot
410 first insulation layer
420 second insulation layer
611 movable comb electrode
612 fixed feedback comb electrode
620 lower comb electrode lead groove

### DETAILED DESCRIPTION

The specific embodiments are described below to illustrate the implementation of the present disclosure, and those skilled in the art can easily understand other advantages and effects of the present disclosure from the content disclosed in this specification. The present disclosure can also be implemented or applied in other specific embodiments. The details provided in this description can be modified or altered in various ways based on different perspectives and applications without departing from the spirit of the present disclosure.

It should be noted that the illustrations provided in the following embodiments are merely schematic representations to explain the basic concepts of this application. Therefore, the figures only show components related to this application and are not drawn according to the actual number, shape, and size of components in practice. The actual implementation may involve variations in the type, quantity, position relationship, and proportions of the components, and the layout of the components could be more complex.

### Embodiment 1

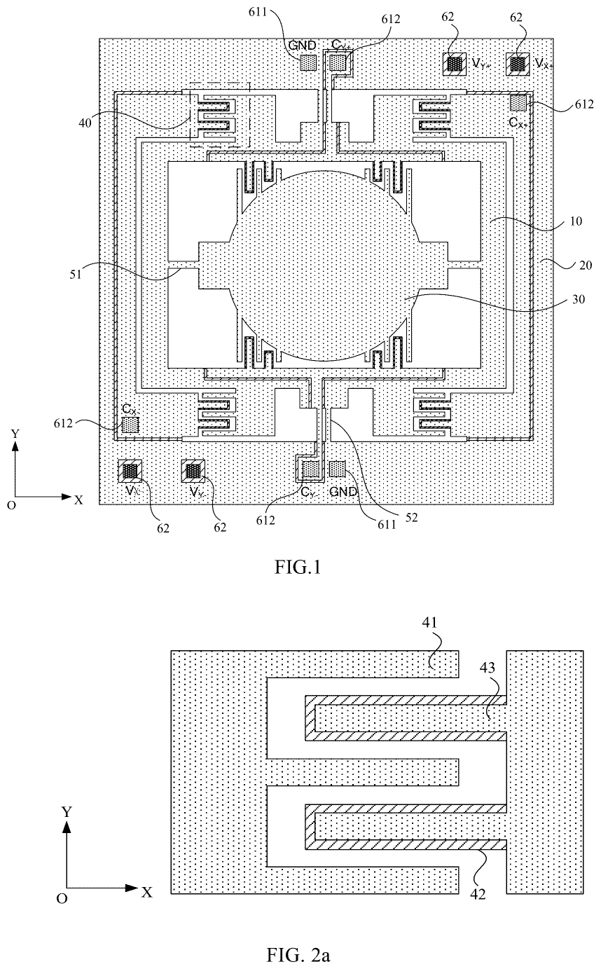

The present embodiment provides a dual-axis angle feedback MEMS micromirror, as shown in FIG. 1. The MEMS micromirror includes an inner frame 10, an outer frame 20, a movable reflector 30 and comb structures 40.

As shown in FIG. 1, the movable reflector 30 is disposed within the inner frame 10, and the outer frame 20 is disposed around the inner frame 10. As an example, first elastic beams 51 are symmetrically disposed on two sides of the movable reflector 30 along a first direction (X-axis direction shown in FIG. 1) for connecting the inner frame 10 to the movable reflector 30, and second elastic beams 52 are symmetrically disposed on two sides of the movable reflector 30 along a second direction (Y-axis direction shown in FIG. 1) perpendicular to the first direction for connecting the inner frame 10 to the outer frame 20.

As shown in FIG. 1, a first subset of the comb structures 40 are provided between the inner frame 10 and the movable reflector 30 for driving the movable reflector 30 to rotate with the first elastic beams 51 as the axis. A second subset of the comb structures 40 are further provided between the inner frame 10 and the outer frame 20 for driving the movable reflector 30 to rotate with the second elastic beams 52 as the axis.

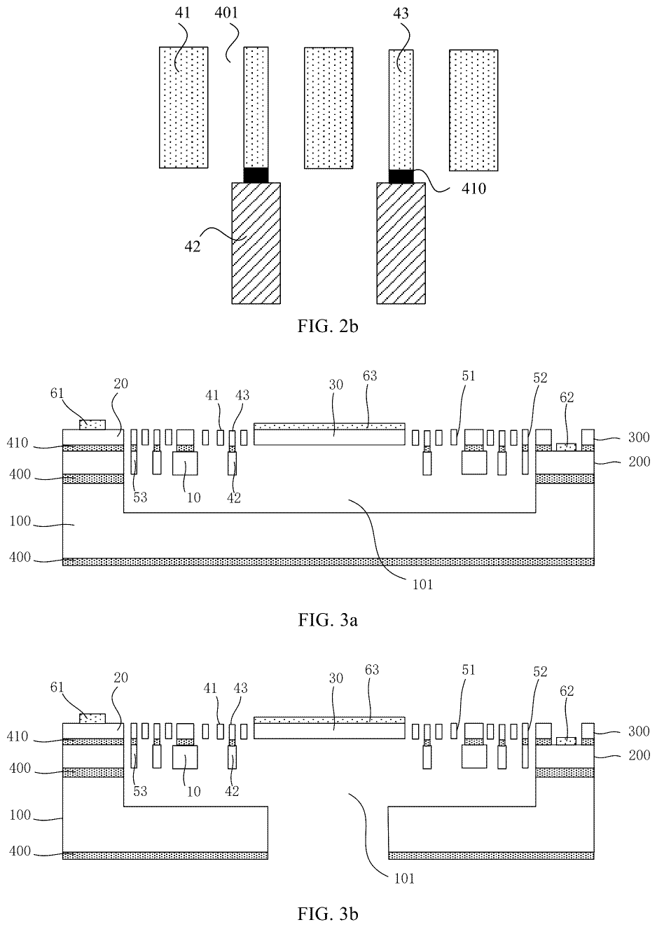

As shown in FIGS. 2a to 2b, each of the comb structures 40 includes movable combs 41, fixed drive combs 42 and fixed feedback combs 43. The fixed feedback combs 43 are disposed above the fixed drive combs 42, as shown in FIG. 2b. The fixed feedback combs and the movable combs 41 have overlapping extension lengths along the Z axis (the direction perpendicular to the paper of FIG. 1), as shown in FIG. 2b. Projections of the fixed drive combs 42 and the movable combs 41 onto the horizontal plane (i.e., the X-Y plane) are staggered. As the movable combs 41 rotate, the capacitance formed between each of the movable combs 41 and a corresponding one of the fixed feedback combs 43 changes. Therefore, the variation in capacitance provides real-time feedback of the rotation angle. For example, when the movable reflector 30 rotates with the first flexural beam 51 as the axis, the capacitance between each of the movable combs 41 and the corresponding fixed feedback comb 43 (those located between the inner frame 10 and the movable reflector 30), decreases simultaneously. When the movable reflector 30 rotates with the second elastic beam 52 as the axis, the capacitance between each of the movable combs 41 and the corresponding fixed feedback comb 43 (those located between the inner frame 10 and the outer frame 20), decreases simultaneously.

As an example, an isolation slot 401 or an insulation filling slot (not shown in the figures) is provided between two adjacent fixed drive combs 42, two adjacent fixed feedback combs 43, and two adjacent fixed feedback comb 43 and movable comb 41. A first insulation layer 410 is provided between the fixed feedback combs 43 and the fixed drive combs 42 to achieve electrical insulation.

As shown in FIG. 1, the movable combs 41, the fixed drive combs 42 and the fixed feedback combs 43 of the comb structures between the inner frame 10 and the outer frame 20 extend in the first direction (the X-axis direction shown in FIG. 1); these movable combs 41 are connected to the outer sides of the inner frame 10, and these fixed drive combs 42 and fixed feedback combs 43 are connected to the inner sides of the outer frame 20. The movable combs 41, the fixed drive combs 42 and the fixed feedback combs 43 of the comb structures between the inner frame 10 and the movable reflector 30 extend in the second direction (the Y-axis direction shown in FIG. 1); these movable combs 41 are connected to the movable reflector 30; these fixed drive combs 42 and the fixed feedback combs 43 are connected to the inner sides of the inner frame 10. As an example, in a projection plane formed by the first direction and the second direction (the X-Y plane shown in FIG. 2a), a length of the fixed feedback combs 43 is less than or equal to a length of the fixed drive combs 42, and a width of the fixed feedback combs 43 are less than or equal to a width of the fixed drive combs 42.

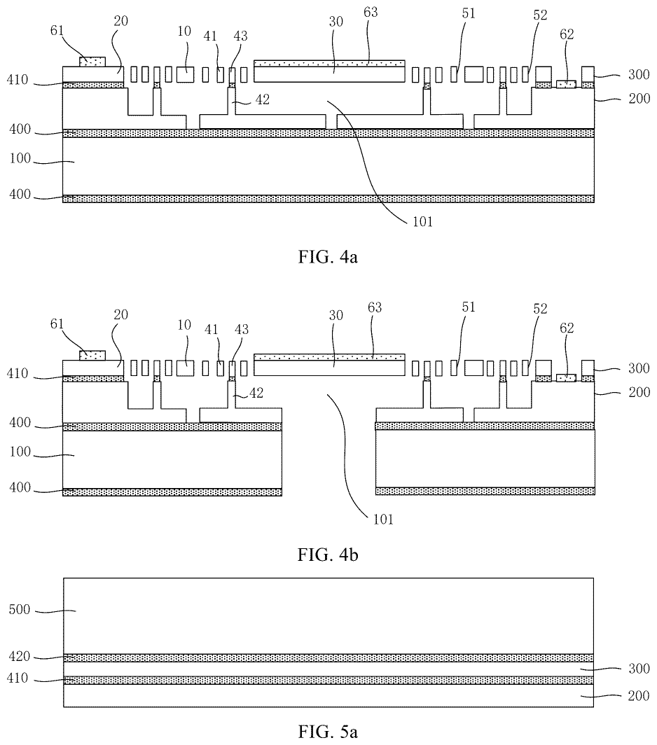

As shown in FIGS. 3a and 3b, the MEMS micromirror further includes a substrate 100. As an example, the substrate 100 is disposed below the inner frame 10, the outer frame 20, the movable reflector 30, the first elastic beams 51, the second elastic beams 52, and the comb structures 40. An insulation layer 400 is provided on a bottom surface of the substrate 100. A slot 101 is provided in the substrate 100 to provide space for the movement of the movable reflector 30, the first elastic beams 51, the second elastic beams 52, the comb structures 40, and the inner frame 10. In one embodiment, the slot 101 is a blind slot, as shown in FIG. 3. In another embodiment, the slot 101 is a through slot, as shown in FIG. 3b.

As shown in FIGS. 3a and 3b, the MEMS micromirror further includes supplementary elastic beams 53, upper comb electrodes 61, lower comb electrodes 62, and a metal reflective layer 63. As an example, the supplementary elastic beams 53 are disposed below the second elastic beams 52. The supplementary elastic beams 53 are isolated from the second elastic beams 52 by the first insulation layer 410. The upper comb electrodes 61 and the lower comb electrodes 62 are disposed on the outer frame 20. As shown in FIG. 1, each of the upper comb electrodes 61 includes a movable comb electrode 611 and a fixed feedback comb electrode 612. The metal reflective layer 63 is disposed on the surface of the movable reflector 30.

As an example, the supplementary elastic beams 53 and the fixed drive combs 42 are disposed in a first device layer 200. The insulation layer 400 is provided between the first device layer 200 and the substrate 100. The movable reflector 30, the first elastic beams 51, the second elastic beams 52, the movable combs 41, and the fixed feedback combs 43 are disposed in a second device layer 300. A first insulation layer 410 is provided between the second device layer 300 and the first device layer 200. The upper comb electrodes 61 are provided on the surface of the second device layer 300, and the lower comb electrodes 62 are provided on the surface of the first device layer 200 while being exposed on the surface of the outer frame. In one embodiment, the movable combs 41 are led out to the movable comb electrodes 611 via the first elastic beams 51 and the second elastic beams 52. The fixed feedback combs 43 connected to the inner sides of the inner frame 10 are led out to the fixed feedback comb electrode 612 via the first elastic beams 51 and the second elastic beams 52. The fixed feedback combs 43 connected to the inner sides of the outer frame 20 are led out through internal connections in the layer to the corresponding fixed feedback comb electrodes 612. The fixed drive combs 42 connected to the inner sides of the inner frame 10 are led out to the corresponding lower comb electrodes 62 via the supplementary elastic beams 53. The fixed drive combs 42 connected to the inner sides of the outer frame 20 are led out through internal connections in the layer to the corresponding lower comb electrodes 62, and the different electrodes are isolated from each other.

As an example, a laser, a position detector, and a lens (not shown in the drawings) are provided directly below the movable reflector 30. A beam emitted by the laser is reflected by the backside of the movable reflector 30 and then received by the position detector. By measuring the intensity or position of the received beam, the rotation angle of the movable reflector 30 can be fed back. Therefore, if capacitive feedback is not used, photoelectric feedback can also be achieved by using lasers, position detectors, lenses, etc. This enables compatibility with both capacitive and photoelectric feedback systems for closed-loop angle control, thereby making the design scheme more flexible.

### Embodiment 2

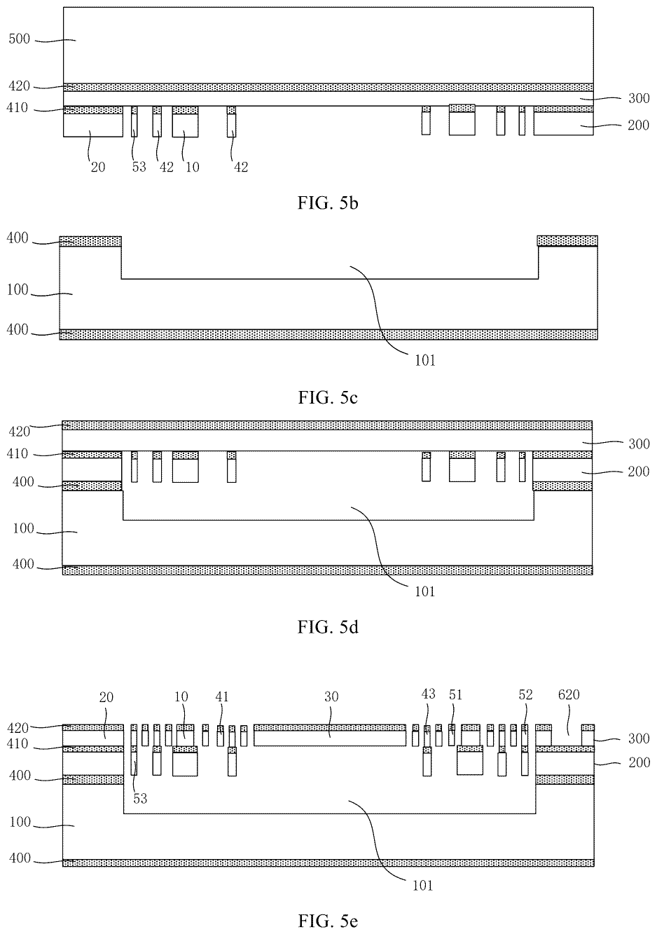

The present embodiment provides a dual-axis angle feedback MEMS micromirror, as shown in FIGS. 4a and 4b. The MEMS micromirror includes an inner frame 10, an outer frame 20, a movable reflector 30 and comb structures 40. Most parts of the MEMS micromirror provided in this embodiment and Embodiment 1 are the same. The differences are as follows:

As shown in FIGS. 4a to 4b, the MEMS micromirror in Embodiment 2 includes upper comb electrodes 61 and lower comb electrodes 62 disposed on the outer frame 20. As shown in FIG. 1, the upper comb electrodes 61 include a movable comb electrode 611 and a fixed feedback comb electrode 612. The upper comb electrodes 61 are provided on the surface of the second device layer 300, and the lower comb electrodes 62 are provided on the surface of the first device layer 200 while being exposed on the surface of the outer frame. In one embodiment, the movable combs 41 are led out to the movable comb electrode 611 via the first elastic beams 51 and the second elastic beams 52. The fixed feedback combs 43 connected to the inner sides of the inner frame 10 are led out to the fixed feedback comb electrodes 612 via the first elastic beams 51 and the second elastic beams 52. The fixed feedback combs 43 connected to the inner sides of the outer frame 20 are led out through internal connections in the layer to the corresponding fixed feedback comb electrodes 612. The fixed drive combs 42 are led out through internal connections in the layer to the corresponding lower comb electrodes 62, and the different electrodes are isolated from each other.

As an example, the slot 101 is provided in the substrate 100 to provide space for the movement of the movable reflector 30, the first elastic beams 51, the second elastic beams 52, the comb structures 40, and the inner frame 10. In one embodiment, the slot 101 is a blind slot, as shown in FIG. 3. In another embodiment, the slot 101 is a through slot, as shown in FIG. 4b.

### Embodiment 3

The present embodiment provides a manufacturing method of the MEMS micromirror as described in the Embodiment 1, and the method includes the following steps:

S1: providing a bonded structure including a substrate, a first device layer, a first insulation layer, a second device layer, and a second insulation layer stacked sequentially, wherein at least fixed drive combs are formed in the first device layer;

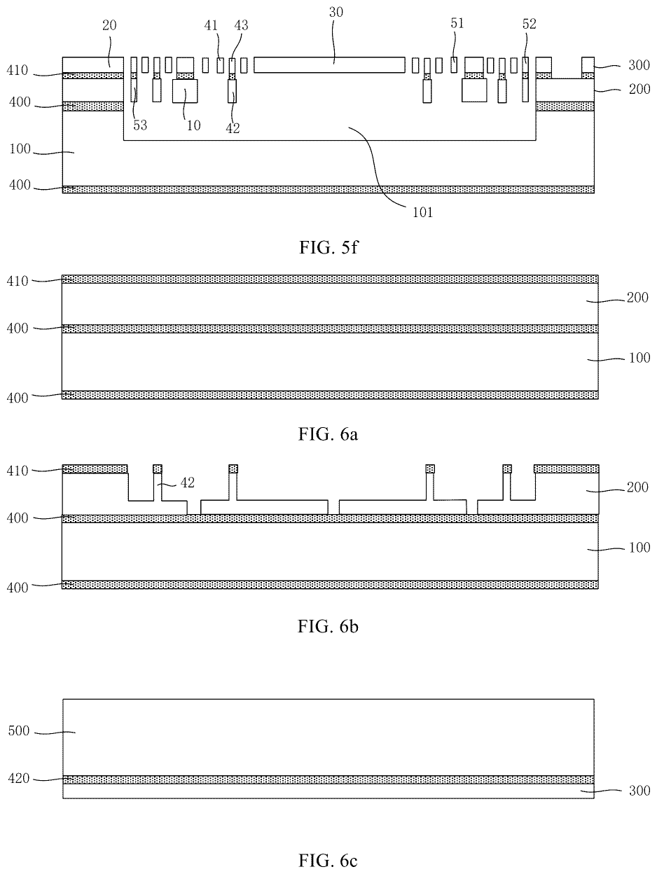

As shown in FIG. 5a, a dual-device layer stack is provided. The dual-device layer stack includes a first device layer 200, a first insulation layer 410, a second device layer 300, a second insulation layer 420, and a base layer 500 stacked sequentially. As an example, the dual-device layer stack includes, but is not limited to, the two device layers that are SOI low-resistance silicon wafers and the base layer 500 that is a high-resistance silicon wafer. Therefore, the first device layer 200, the second device layer 300, and the base layer 500 are silicon material layers, and the first insulation layer 410 and the second insulation layer 420 are silicon oxide layers. Certainly, according to actual requirements, the dual-device layer stack may also be other materials, for example, the first device layer 200, the second device layer 300, and/or the base layer 500 are semiconductor material layers such as germanium, germanium-silicon, and silicon carbide, and the first insulation layer 410 and/or the second insulation layer 420 are dielectric layers such as silicon nitride, which is not strictly limited herein.

As shown in FIG. 5b, the first device layer 200 and the first insulation layer 410 are etched to form the fixed drive combs 42, the substructure of the inner frame 10, the substructure of the outer frame 20, and the supplementary elastic beams 53 in the first device layer 200. Referring to FIG. 1, the fixed drive combs 42 of the comb structures disposed between the inner frame 10 and the outer frame 20 are connected to the inner sides of the outer frame 20. The fixed drive combs 42 of the comb structures disposed between the inner frame 10 and the movable reflector 30 are connected to the inner sides of the inner frame 10.

In this step, a photoresist layer is applied onto the surface of the first device layer 200, a desired pattern is then defined by patterning, after which the first device layer 200 is etched to obtain the fixed drive combs 42, the inner frame 10, the outer frame 20, and the supplementary elastic beams 53 by dry and/or wet etching. As an example, the fixed drive combs 42 connected to the inner sides of the inner frame 10 are subsequently led out to the corresponding lower comb electrodes 62 via the supplementary elastic beams 53, and the fixed drive combs 42 connected to the inner sides of the outer frame 20 are subsequently led out through internal connections in the layer to the corresponding lower comb electrodes 62. Multiple fixed drive combs 42 are spaced apart in parallel, and gaps between the multiple fixed drive combs 42 expose the second device layer 300.

As shown in FIG. 5c, a substrate 100 is provided. An insulation layer 400 formed on both top and bottom surfaces of the substrate 100, respectively. For example, the substrate 100 can be a silicon substrate, and a double-sided insulation layer is formed by thermal oxidation. A slot 101 is formed in the substrate 100, and an opening of the slot 101 is formed on the top surface of the substrate 100. The slot 101 is used to provide space for the movement of subsequent preparations such as the movable reflector 30, the inner frame 10, the comb structures 40, the first elastic beams 51 and the second elastic beams 52.

As shown in FIG. 5d, a surface of the first device layer 200 of the dual-device layer stack is bonded to the top surface of the substrate 100, and the base layer 500 is removed by etching and/or chemical mechanical polishing, etc., to form the bonded structure. As an example, the fixed drive combs 42, the inner frame 10, and the supplementary elastic beams 53 are disposed above the slot 101.

S2: etching the second insulation layer and the second device layer to form movable combs, fixed feedback combs, a movable reflector, first elastic beams, second elastic beams, and lower comb electrode lead grooves in the second device layer;

As shown in FIG. 5e, the second insulation layer 420 and the second device layer 300 are etched to form a top structure of the inner frame 10, a top structure of the outer frame 20, the movable combs 41, the fixed feedback comb 43, the movable reflector 30, the first elastic beams 51, the second elastic beams 52, and the lower comb electrode lead grooves 620 in the second device layer 300. Referring to FIGS. 1 and 2b, the movable reflector 30 is disposed inside the inner frame 10 and connected to the inner frame 10 by the first elastic beams 51. The outer frame 20 is disposed around the inner frame 10 and is connected to the inner frame 10 by the second elastic beams 52. The fixed feedback combs 43 are provided coaxially with the fixed drive combs 42, and the projections of the fixed drive combs 42 and the movable combs 41 onto the horizontal plane are staggered.

Referring to FIG. 1, in the comb structures between the inner frame 10 and the outer frame 20, the movable combs 41 are connected to the outer sides of the inner frame 10, and the fixed drive combs 42 and the fixed feedback combs 43 are connected to the inner sides of the outer frame 20. In the comb structures between the inner frame 10 and the movable reflector 30, the movable combs 41 are connected to the movable reflector 30, and the fixed drive combs 42 and the fixed feedback combs 43 are connected to the inner sides of the inner frame 10.

S3: removing the second insulation layer and the exposed first insulation layer.

As an example, the second insulation layer 420 and the exposed first insulation layer 410 are removed to form the structure shown in FIG. 5f.

Then, upper comb electrodes 61 are formed on the surface of the outer frame 20 in the second device layer 300. Referring to FIG. 1, the upper comb electrodes 61 include a movable comb electrode 611 and a fixed feedback comb electrode 612. A metal reflective layer 63 is formed on the surface of the movable reflector 30, and lower comb electrodes 62 exposed on the surface of the outer frame are formed in the lower comb electrode lead grooves 620. Finally, the structure shown in FIG. 3a is formed.

As an example, an upper surface of the second device layer 300 is the surface of the outer frame 20. The upper comb electrodes 61 are formed on the surface of the outer frame 20. The upper comb electrodes 61 include the movable comb electrode 611 and the fixed feedback comb electrode 612, where the movable comb electrode 611 is led out and connected to the movable combs 41 via the first elastic beam 51, the second elastic beam 52. The movable comb electrode 611 is generally a shared ground electrode. The lower comb electrode lead grooves 620 expose the first device layer 200 to enable the lower comb electrodes 62 to be exposed on the surface of the outer frame 20. Referring to FIG. 1, generally, four lower comb electrodes 62 are provided, where a first lower comb electrode and a second lower comb electrode are independently electrically connected to the fixed drive combs 42, which are connected to the inner sides of the inner frame 10, so that different voltages can be applied to rotate the movable reflector 30 with the first elastic beams 51 as an axis. A third lower comb electrode and a fourth lower comb electrode are independently electrically connected to the fixed drive combs 42, which are connected to the inner sides of the outer frame 20, so that different voltages can be applied to rotate the movable reflector 30 with the second elastic beams 52 as an axis. Different lower comb electrodes are isolated from each other. The metal reflective layer 63 and each of the electrodes can be formed by the same processes or different processes, including but not limited to the sputtering process, and the material includes, but is not limited to gold, silver, copper, aluminum, or other single metals or alloys.

In another embodiment, after forming the structure shown in FIG. 3a, a step of perforating the bottom surface of the substrate 100 is further included. As shown in FIG. 3b, the slot 101 in the substrate 100 is a through slot to provide space for the movement of the movable reflector 30, the first elastic beams 51, the second elastic beams 52, the comb structures 40, and the inner frame 10.

### Embodiment 4

The present embodiment provides a manufacturing method of the MEMS micromirror as described in the Embodiment 2, the method includes the following steps:

S1: providing a bonded structure including a substrate, a first device layer, a first insulation layer, a second device layer, and a second insulation layer stacked sequentially, wherein at least fixed drive combs are formed in the first device layer;

S2: etching the second insulation layer and the second device layer to form movable combs, fixed feedback combs, a movable reflector, first elastic beams, second elastic beams, and lower comb electrode lead grooves in the second device layer;

S3: removing the second insulation layer and the exposed first insulation layer.

The manufacturing method of the MEMS micromirror provided in this embodiment is mostly the same as that in Embodiment 3, and the difference lies in the formation of the bonded structure. The bonded structure includes a single device layer stack.

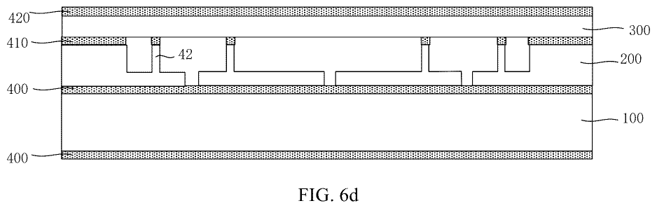

As shown in FIG. 6a, a first single device layer stack is provided. The first single device layer stack includes a substrate 100, a first device layer 200, and a first insulation layer 410 sequentially stacked. An insulation layer 400 is formed on both top and bottom surfaces of the substrate 100. For example, the substrate 100 can be a silicon substrate, and a double-sided insulation layer is formed by thermal oxidation.

As shown in FIG. 6b, the first device layer 200 and the first insulation layer 410 are etched to form fixed drive combs 42 in the first device layer 200.

Then, a second single device layer stack is provided. As shown in FIG. 6c, the second single device layer stack includes a second device layer 300, a second insulation layer 420, and a base layer 500 sequentially stacked. A surface of the first device layer 200 of the first single device layer stack is bonded to a surface of the second device layer 300 of the second single device layer stack to form the bonded structure. Finally, the base layer 500 is removed to form the structure shown in FIG. 6d.

In the MEMS micromirror prepared in this embodiment, the movable combs 41 are led out to the movable comb electrode 611 via the first elastic beams 51 and the second elastic beams 52. The fixed feedback combs 43 connected to the inner sides of the inner frame 10 are led out to the fixed feedback comb electrode 612 via the first elastic beams 51 and the second elastic beams 52. The fixed feedback combs 43 connected to the inner sides of the outer frame 20 are led out through internal connections in the layer to the corresponding fixed feedback comb electrodes 612. The fixed drive combs 42 are led out through internal connections in the layer to the corresponding lower comb electrodes 62, and the different electrodes are isolated from each other.

The embodiments described above serve merely as illustrative examples of the principles and effects of the present invention, and are not intended to serve as limitations on the present invention. Persons skilled in the art may modify or alter these embodiments without departing from the spirit and scope of the present disclosure. Accordingly, all equivalent modifications or alterations accomplished by persons having ordinary knowledge in the art without departing from the spirit and technical ideas disclosed herein shall still be covered by the claims of the present invention.

1. A dual-axis angle feedback MEMS micromirror, comprising:
an inner frame; an outer frame, disposed around the inner frame;
a movable reflector, disposed inside the inner frame;
elastic beams, comprising first elastic beams and second elastic beams, wherein the first elastic beams are symmetrically disposed on two sides of the movable reflector along a first direction for connecting the inner frame to the movable reflector, and the second elastic beams are symmetrically disposed on two sides of the movable reflector along a second direction perpendicular to the first direction for connecting the inner frame to the outer frame; and
comb structures, disposed between the inner frame and the movable reflector, and between the inner frame and the outer frame, and configured to respectively drive the movable reflector to rotate around the first elastic beams or the second elastic beams;
wherein each of the comb structures comprises movable combs, fixed drive combs and fixed feedback combs; wherein the fixed feedback combs are disposed above the fixed drive combs and in the same plane as the movable combs, and the projections of the fixed drive combs and the movable combs are staggered in a horizontal plane; wherein the fixed drive combs of a first subset of the comb structures disposed between the inner frame and the movable reflector are connected to the inner sides of the inner frame, and the fixed drive combs of a second subset of the comb structures disposed between the inner frame and the outer frame are connected to the inner sides of the outer frame.

2. The MEMS micromirror according to claim 1, wherein the movable combs, the fixed drive combs, and the fixed feedback combs of the comb structures between the inner frame and the outer frame extend in the first direction, and the movable combs, the fixed drive combs and the fixed feedback combs of the comb structures between the inner frame and the movable reflector extend in the second direction.

3. The MEMS micromirror according to claim 1, wherein in the projection plane formed by the first direction and the second direction, a length of the fixed feedback combs is less than or equal to a length of the fixed drive combs, and a width of the fixed feedback combs is less than or equal to a width of the fixed drive combs.

4. The MEMS micromirror according to claim 1, wherein an isolation slot or an insulation filling slot is provided between two adjacent fixed drive combs, two adjacent fixed feedback combs, and two adjacent fixed feedback comb and movable comb, wherein a first insulation layer is provided between the fixed feedback combs and the fixed drive combs.

5. The MEMS micromirror according to claim 1, further comprising a substrate disposed below the inner frame, the outer frame, the movable reflector, the elastic beams and the comb structures, wherein a slot is provided in the substrate to provide space for the movement of the movable reflector, the elastic beams, the comb structures and the inner frame; wherein the slot is a blind slot or a through slot.

6. The MEMS micromirror according to claim 1, further comprising:
supplementary elastic beams, disposed below the second elastic beams and isolated from the second elastic beams;
upper comb electrodes and lower comb electrodes disposed on the outer frame, wherein the upper comb electrodes comprise a movable comb electrode and a fixed feedback comb electrode;
wherein the movable combs are led out to the movable comb electrode via the elastic beams, the fixed feedback combs connected to the inner sides of the inner frame are led out to the fixed feedback comb electrode via the elastic beams, the fixed feedback combs connected to the inner sides of the outer frame are led out through internal connections in the layer to the corresponding fixed feedback comb electrode, the fixed drive combs connected to the inner sides of the inner frame are led out to the corresponding lower comb electrodes via the supplementary elastic beams, and the fixed drive combs connected to the inner sides of the outer frame are led out through internal connections in the layer to the corresponding lower comb electrodes; wherein the different electrodes are isolated from each other.

7. The MEMS micromirror according to claim 1, further comprising:
upper comb electrodes and lower comb electrodes disposed on the outer frame, wherein the upper comb electrodes comprise a movable comb electrode and a fixed feedback comb electrode;
wherein the movable combs are led out to the movable comb electrode via the elastic beams, the fixed feedback combs connected to the inner sides of the inner frame are led out to the fixed feedback comb electrode via the elastic beams, the fixed feedback combs connected to the inner sides of the outer frame are led out through internal connections in the layer to the corresponding fixed feedback comb electrode, and the fixed drive combs are led out through internal connections in the layer to the corresponding lower comb electrodes; wherein the different electrodes are isolated from each other.

8. A manufacturing method of a dual-axis angle feedback MEMS micromirror, wherein the method is used for preparing the MEMS micromirror according to claim 1, comprising the following steps:
providing a bonded structure including a substrate, a first device layer, a first insulation layer, a second device layer, and a second insulation layer stacked sequentially, wherein at least fixed drive combs are formed in the first device layer;
etching the second insulation layer and the second device layer to form movable combs, fixed feedback combs, a movable reflector, first elastic beams, second elastic beams and lower comb electrode lead grooves in the second device layer, wherein the fixed feedback combs are provided coaxially with the fixed drive combs, and the projections of the fixed drive combs and the movable combs onto a horizontal plane are staggered; and
removing the second insulation layer and the exposed first insulation layer;
wherein a metal reflective layer is formed on the surface of the movable reflector, a movable comb electrode and a fixed feedback comb electrode are formed on the surface of the outer frame in the second device layer, and lower comb electrodes exposed on the surface of the outer frame are formed in the lower comb electrode lead grooves; wherein the different electrodes are isolated from each other.

9. The method according to claim 8, wherein forming the bonded structure comprises:
providing a dual-device layer stack comprising a first device layer, a first insulation layer, a second device layer, a second insulation layer, and a base layer stacked sequentially;
etching the first device layer and the first insulation layer to form the fixed drive combs and supplementary elastic beams in the first device layer;
providing a substrate, wherein a slot is formed in the substrate, and an opening of the slot is formed on a top surface of the substrate;
bonding a surface of the first device layer of the dual-device layer stack with the top surface of the substrate to form the bonded structure, wherein the fixed drive combs, the inner frame and the supplementary elastic beams are disposed above the slot; and
removing the base layer.

10. The method according to claim 8, wherein forming the bonded structure comprises:
providing a first single device layer stack including a substrate, a first device layer, and a first insulation layer stacked sequentially;
etching the first device layer and the first insulation layer to form the fixed drive combs in the first device layer;
providing a second single device layer stack including a second device layer, a second insulation layer and a base layer stacked sequentially;
bonding a surface of the first device layer of the first single device layer stack to a surface of the second device layer of the second single device layer stack to the bonded structure; and
removing the base layer.
